(19) United States
(12) Patent Application Publication
(10) Pub. No.: US 2017/0018315 A1
(43) Pub. Date: Jan. 19, 2017

(54) TEST SYSTEM AND TEST METHOD

(71) Applicant: SK hynix Inc., Gyeonggi-do (KR)

(72) Inventor: Chol Su CHAE, Gyeonggi-do (KR)

(21) Appl. No.: 14/957,320

(22) Filed: Dec. 2, 2015

(30) Foreign Application Priority Data
Jul. 17, 2015 (KR) 10-2015-0101798

(51) Int. Cl. G11C 29/38; G11C 29/44

(52) U.S. Cl. CPC G11C 29/38; G11C 29/44

(57) ABSTRACT

A test system may include a memory device suitable for reading a stored data chunk; and a test device suitable for calculating a cumulative failure probability that the data chunk will contain a s predetermined number of error bits or less and decoding for the data chunk will fail.

### CROSS-REFERENCES TO RELATED APPLICATION

The present application claims priority under 35 U.S.C. §119(a) to Korean application number 10-2015-0101798, filed on July, 17, 2015, in the Korean Intellectual Property Office, which is incorporated herein by reference in its entirety.

### BACKGROUND

1. Technical Field

Various embodiments relate to a test system, and more particularly, to a system which performs a test on a memory device.

2. Related Art

A memory device is used to store data. The memory device is classified into a nonvolatile memory device and a volatile memory device.

Data read from the memory device may include an error. In order to correct the error included in the data, a system including the memory device also includes an ECC (Error Correcting Code) unit.

### SUMMARY

In an embodiment of the present invention, a test system may include a memory device suitable for reading a stored data chunk; and a test device suitable for calculating a cumulative failure probability that the data chunk will contain a predetermined number of error bits or less and decoding for the data chunk will fail.

In an embodiment of the present invention, a test system may include a memory device; and a test device suitable for, calculating a first probability corresponding to each of values of a random variable, which is a number of error bits, for a data chunk read from the memory device, calculating a second probability that error correction for error bits in each of the values of the random variable will fail, and calculating an effective number corresponding to a number of error bits which guarantees a target decoding failure probability to the memory device based on the first probability and the second probability.

In an embodiment of the present invention, a test method may include calculating a first probability corresponding to each of values of the random variable, which is a number of error bits, for a data chunk read from a memory device; calculating a second probability that error correction for error bits in each of the values of the random variable will fail; and calculating an effective number corresponding to a number of error bits which guarantees a target decoding failure probability to the memory device based on the first probability and the second probability.

### BRIEF DESCRIPTION OF THE DRAWINGS

Features, aspects, and embodiments are described in conjunction with the attached drawings, in which: to an embodiment of the present invention;

FIG. 2 is a block diagram illustrating a memory device of FIG. 1;

FIG. 3 is a table illustrating a method of a control unit for calculating a first probability corresponding to the respective values of random variable for a data chunk read from the memory device;

FIG. 4 is a graph illustrating the first probabilities corresponding to the respective values of the random variable of FIG. 3;

FIG. 5 is a table for illustrating a method of the control unit for calculating a second probability corresponding to the respective values of the random variable of FIG. 3;

FIG. 6 is a graph illustrating the second probabilities for the respective values of the random variable of FIG. 3;

FIG. 7 is a table for illustrating a method of the control unit for calculating an effective number for a target decoding failure probability based on the first and second probabilities of FIGS. 3 and 4;

FIGS. 8, 9, 10, and 11 are flowcharts illustrating a test method according to an embodiment of the present invention;

FIG. 12 is a block diagram illustrating a data storage device according to an embodiment of the present invention; and

FIG. 13 is a block diagram illustrating a data processing system to which the data storage device according to the embodiment of the present invention is applied,

### DETAILED DESCRIPTION

Hereinafter, a data storage device and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more dearly depict certain features of the invention. While particular terminology is used, it is to be appreciated that the terminology used is for describing particular embodiments only and is not intended to limit the scope of the present invention.

FIG. 1 is a block diagram illustrating a test system 10 according to an embodiment of the present invention.

The test system 10 may include a test device 100 and a memory device 200.

The test device 100 may include a control unit 110 and an ECC unit 120.

The control unit 110 may control overall operations of the test system 10. In order to perform a test on the memory device 200, the control unit 110 may store data in the memory device 200 and read the stored data from the memory device 200.

The control unit 110 may calculate a cumulative failure probability that a data chunk read from the memory device 200 will include a predetermined number of error bits or less and decoding for the data chunk will fail. The control unit 110 may estimate the performance of the memory device by comparing the calculated cumulative failure probability to a predetermined target decoding failure probability.

When a random variable indicates the number of error bits, the control unit 110 may calculate a first probability or an occurrence probability P1 corresponding to each of the values of the random variable for the data chunk read from the memory device 200, calculate a second probability or a specific failure probability P2 of error correction failure for error bits in the values of the random variable, and calculate an effective number corresponding to the number of error bits for the target decoding failure probability to the memory device 200 based on the first probability P1 and the second probability P2.

The ECC unit 120 may encode data to be stored in the memory device 200 according to an ECC algorithm and perform decoding to correct an error contained in data read from the memory device 200. The ECC unit 120 may perform encoding and decoding according to a Low Density Parity Check(LDPC) code algorithm based on probability information. When the ECC unit 120 is operated according to the ECC algorithm based on probability information, the maximum number of correctable error bits may not be specified. The maximum number of correctable error bits may represent the decoding performance of the ECC unit 120.

According to the present embodiment, the test system 10 may test whether the target decoding failure probability is guaranteed when decoding is performed on the memory device 200 through the ECC unit 120. When it is determined that the target decoding failure probability is not guaranteed, the reliability of the memory device 200 or the decoding performance of the ECC unit 120 for the memory device 200 may be evaluated to be low. Furthermore, when it is determined that the target decoding failure probability is guaranteed the reliability of the memory device 200 or the decoding performance of the ECC unit 120 for the memory device 200 may be evaluated to be high. Furthermore, the reliability of the memory device 200 or the decoding performance of the ECC unit 120 for the memory device 200 may be evaluated to be higher as the guaranteed target decoding failure probability becomes lower.

The test system 10 may calculate the number of error bits as the effective number, which guarantees the target decoding failure probability to the memory device 200. When the data read from the memory device 200 contains error bits equal to or less than the effective number, the decoding operation of the ECC unit 120 may fail at a probability equal to or less than the target decoding failure probability. Thus, the target decoding failure probability may be guaranteed through the effective number.

The effective number can be separately calculated s regardless of whether the target decoding failure probability is guaranteed to the memory device 200. In particular, however, when the target decoding failure probability is not guaranteed, the effective number may be useful information. That is, when it is determined that the target decoding failure probability is not guaranteed to the memory device 200, the calculated effective number may be suggested as a development standard for the memory device 200. That is, the memory device 200 may be developed to include error bits equal to or less than the effective number in order to satisfy the target decoding failure probability.

Furthermore, the decoding performance of the ECC unit 120 for the memory device 200 may be evaluated on the basis of the effective number. For example, as the calculated effective number becomes higher, the decoding performance of the ECC unit 120 for the memory device 200 may be evaluated to be better.

The memory device 200 may include a nonvolatile memory device or volatile memory device.

The nonvolatile memory devices maintain data stored therein even though power is cut off. The nonvolatile memory devices include flash memory devices such as NAND flash or NOR flash, Ferroelectrics Random Access Memory (FeRAM), Phase-Change Random Access Memory (PCRAM), Magnetoresistive Random Access Memory (MRAM) and/or Resistive Random Access Memory (ReRAM).

Volatile memory devices fail to maintain data stored therein when power is cut off. Volatile memory devices include Static Random Access Memory (SRAM) and Dynamic Random Access Memory (DRAM).

The memory device 200 may store data transmitted from the test device 100 under the control of the test device 100. Furthermore, the memory device 200 may read stored data and transmit the read data to the test device 100.

FIG. 1 illustrates a single memory device 200 included in the test system 10. However, the test system 10 may include a plurality of memory devices. The plurality of memory devices included in the test system 10 may have substantially the same error occurred characteristic or the same specification.

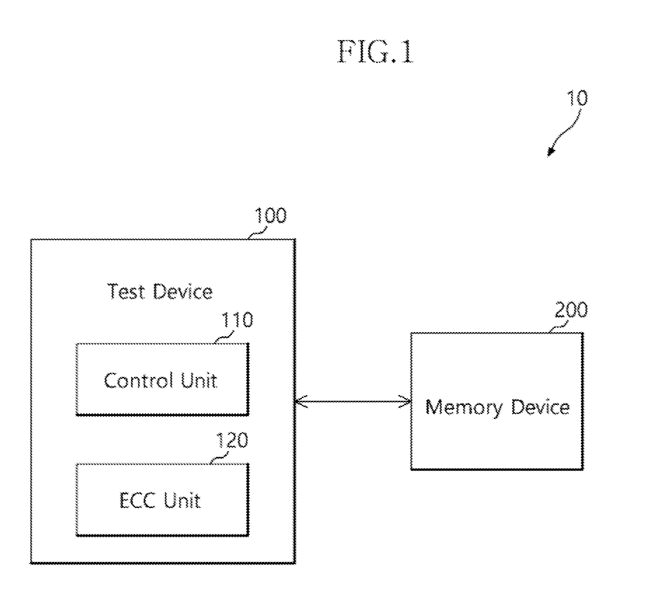

FIG. 2 is a block diagram illustrating the memory device 200 of FIG. 1. The memory device 200 may include a nonvolatile memory device, for example.

The memory device 200 may include a control logic 210, an interface unit 220, an address decoder 230, a data input/output unit 240, and a memory region 250.

The control logic 211 may control overall operations of the memory device 200, such as a write operation and a read operation, under the control of the test device 100. and data with the test device 100, the various control signals including commands and addresses. The interface unit 220 may transmit the various control signals and data to internal units of the memory device 200.

The address decoder 230 may decode a row address and column address transmitted thereto. The address decoder 230 may selectively drive word lines WL according to the decoding result for the row address. The address decoder 230 may control the data input/output unit 240 to selectively drive bit lines BL according to the decoding result for the column address.

The data input/output unit 240 may transmit the data from the interface unit 220 to the memory region 250 through the bit lines BL. The data input/output unit 240 may transmit the read data from the memory region 250 to the interface unit 220 through the bit lines BL.

The memory region 250 may be coupled to the address decoder 230 through the word lines WL and to the data input/output unit 240 through the bit lines BL. The memory region 250 may include a memory cell array. The memory region 250 may include a plurality of memory cells arranged at the respective intersections between the word lines WL and the bit lines BL, and may store data.

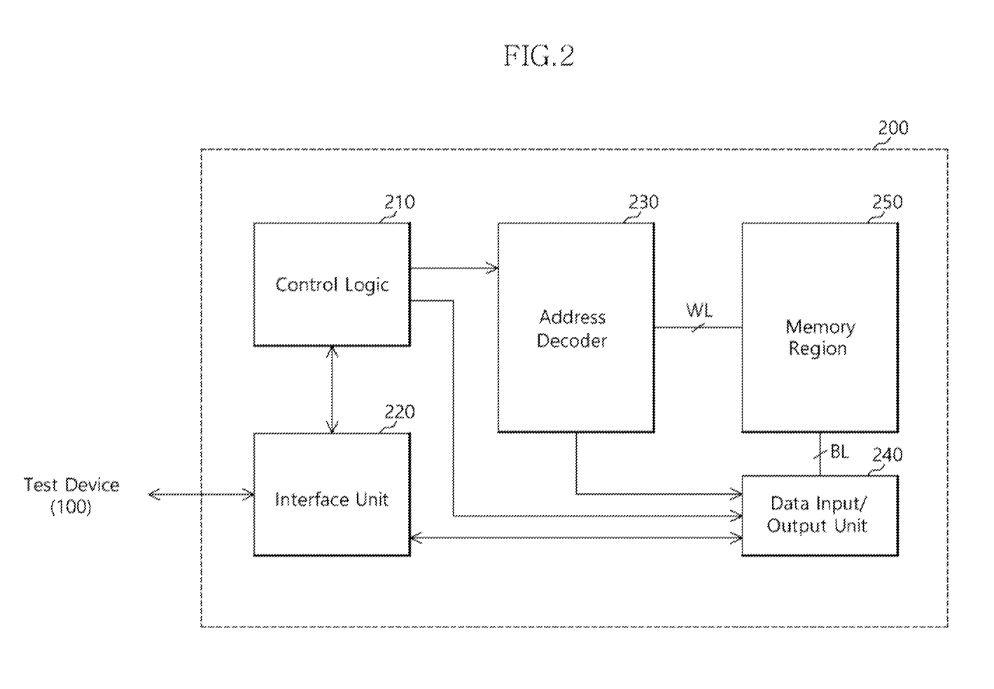

FIG. 3 is a table illustrating a method of the control unit 110 for calculating the first probability or the occurrence probability P1 corresponding to the respective values of random variable for a data chunk read from the memory device 200.

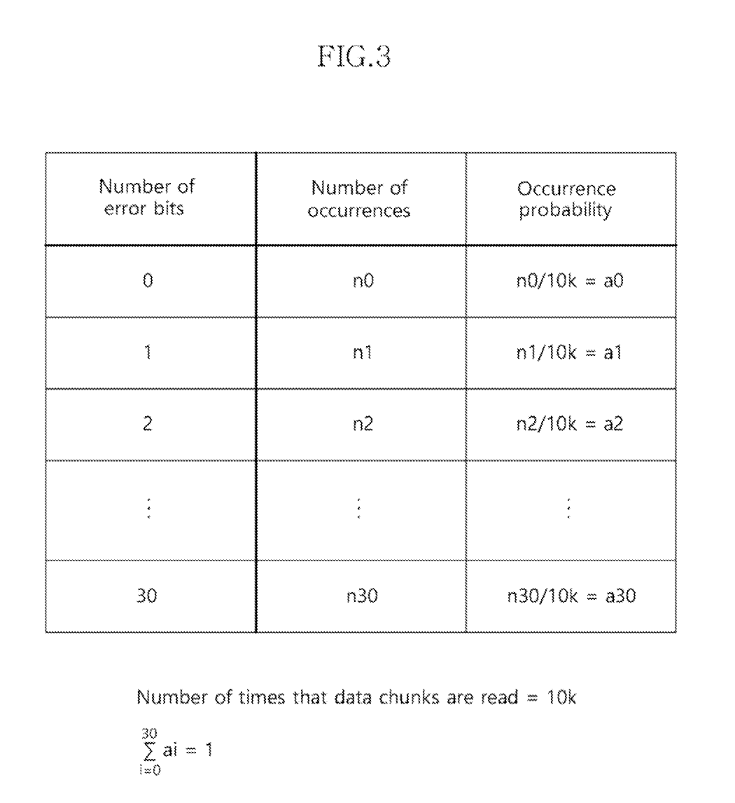

FIG. 4 is a graph illustrating the occurrence probabilities P1 corresponding to the respective values of the random variable of FIG. 3. In FIG. 4, the horizontal axis may indicate the number of error bits corresponding to the random variable, and the vertical axis may s indicate the occurrence probability P1, with which a predetermined number of error bits will occur on a data chunk, corresponding to a specific random variable.

Referring to FIG. 3, when the random variable is the number of error bits, the control unit 110 may calculate the occurrence probabilities P1 corresponding to the respective values of the random variable for a data chunk read from the memory device 200.

The control unit 110 may calculate the occurrence probabilities P1 using a plurality of data chunks as samples. Specifically, the control unit 110 may write a plurality of data chunks to the memory device 200, and read a plurality of data chunks from the memory device 200. For example, the control unit 110 may read the plurality of data chunks “10k” times. The size of a single data chunk may correspond to data process unit of the ECC unit 120.

The control unit 110 may count the number of error bits contained in each of the read data chunks. When it is determined that the number of error bits corresponds to a natural number between “0” and “30”, for example, the random variable may have a value corresponding to a natural number between “0” and “30”. At this time, “30” may correspond to the maximum number of error bits which can be contained in each of the data chunks. That is, the data chunk read from the memory device 200 may contain error bits, a number of which is between a minimum number “0” and a maximum number “30”.

The control unit 110 may calculate the occurrence probability P1 based on the count result. The occurrence probability P1 may be calculated on the basis of the ratio of the number of times that a predetermined number of error bits occurred to the number of times (e.g., “10 k” times) that the plurality of data chunks are read. Specifically, the control unit 110 may count the number of times that error bits corresponding to the value of the random variable occurred while the plurality of data chunks are read (e.g., “10 k” times). The control unit 110 may calculate the occurrence probability P1 based on the count result. For example, when “0” error bits occurred “n0” times during the entire “10k” read times, the occurrence probability P1 of “0” error bits may be calculated as “n0/10 k”.

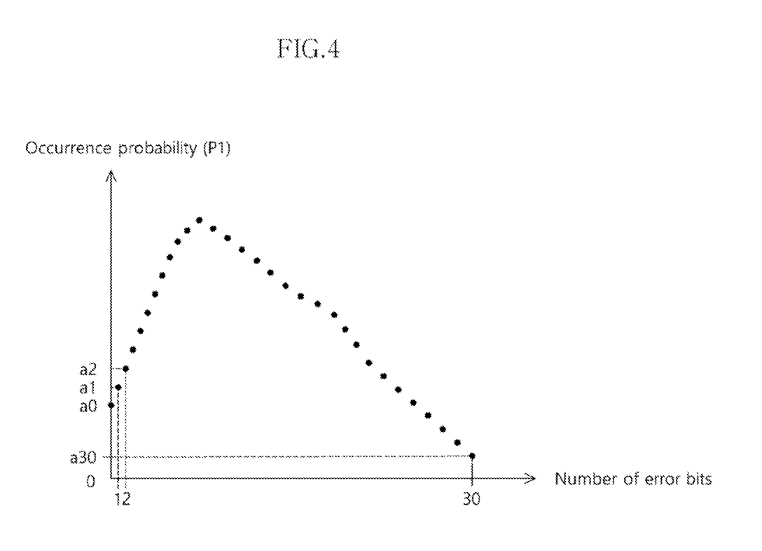

FIG. 5 is a table for illustrating a method of the control unit 110 for calculating the second probability or the specific failure probability P2 corresponding to the respective values of the random variable of FIG. 3.

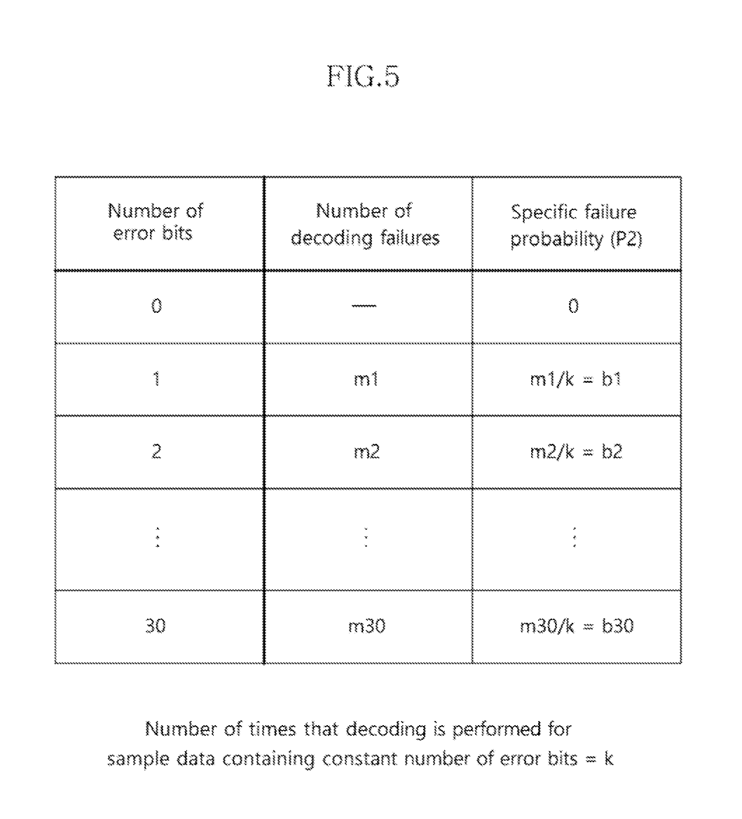

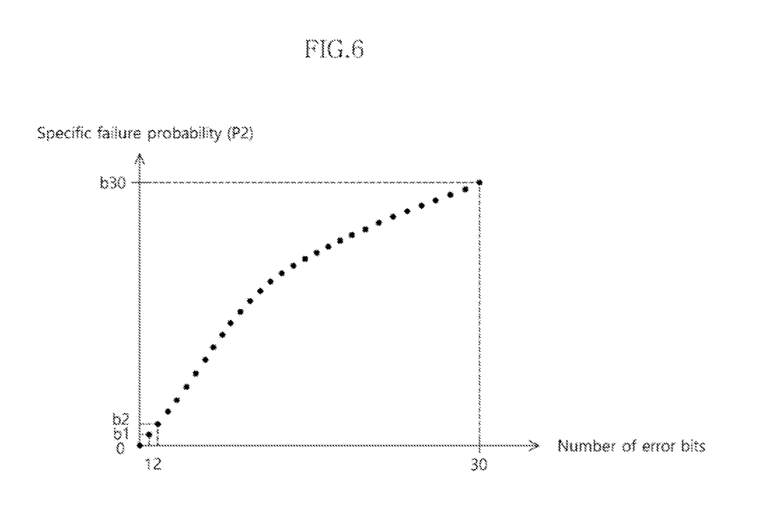

FIG. 6 is a graph illustrating the specific failure probabilities P2 for the respective values of the random variable of FIG. 3. In FIG. 6, the horizontal axis may indicate the number of error bits, which corresponds to the random variable, and the vertical axis may indicate the specific failure probability P2, with which a predetermined number of error bits will fail in error correction on a data chunk, corresponding to a specific random variable.

Referring to FIG. 5, the control unit 110 may calculate the specific failure probability P2 for error bits in the values of the s random variable of FIG. 3. The control unit 110 may control the ECC unit 120 to decode error bits in the values of the random variable in order to calculate the specific failure probability P2. The specific failure probability P2 is independent of the occurrence probability P1 for the memory device 200. The specific failure probability P2 may correspond to the specific characteristic of the ECC unit 120 regardless of the memory device 200 which is tested by the test system 10.

The control unit 110 may control the ECC unit 120 to repetitively decode a plurality of sample data (e.g., “k” sample data), each containing a predetermined number of error bits. Each of the “k” sample data may have a different data pattern and contain a predetermined number of error bits of different locations. The predetermined number may correspond to each of the values of the random variable. The control unit 110 may count the number of times that the ECC unit 120 fails to decode the “k” sample data.

Based on the count result, the control unit 110 may calculate the specific failure probability P2 corresponding to the respective values of the random variable. The specific failure probability P2 may be calculated on the basis of the ratio of the number of times that decoding for a predetermined number of error bits failed to the number of times (e.g., “k” times) that the plurality of sample data were decoded. For example, when decoding for “k” sample data each containing “1” error bit failed “m1” times, the control unit 110 may calculate the specific failure probability P2 corresponding to the “1” error bit as “m1/k”. Furthermore, when decoding for “k” sample data each including “2” error bits failed “m2” times, the control unit 110 may calculate the specific failure probability P2 corresponding to the “2” error bits as “m2/k”.

Referring to FIG. 6, the specific failure probability P2 may increase as the number of error bits increases.

FIG. 7 is a table for illustrating a method of the control unit 110 for calculating an effective number for the target decoding failure probability based on the occurrence probability P1 and the specific failure probability P2 of FIGS. 3 and 4.

Referring to FIG. 7, the control unit 110 may calculate a third probability or an individual failure probability P3 corresponding to the respective values of the random variable of FIG. 3 based on the occurrence probability P1 and the specific failure probability P2. The individual failure probability P3 may indicate the probability that (1) a data chunk read from the memory device 200 will contain a corresponding number of error bits and (2) decoding for the data chunk containing the corresponding number of error bits will fail. In order to calculate the individual failure probability P3, the control unit 110 may perform an operation corresponding to the following equation EQ on each of the values of the random variable. In the following equation, a predetermined number may correspond to each of the values of the random variable.

EQ: Individual failure probability P3=probability that predetermined number of error bits will occur in read data chunk X s probability that decoding for data chunk containing predetermined number of error bits fail=occurrence probability P1 X specific failure probability P2.

The control unit 110 may calculate a cumulative failure probability CP by accumulating the individual failure probabilities P3 for the respective values of the random variable. The cumulative failure probability CP for each of the values of the random variable may indicate the probability that (1) a data chunk read from the memory device 200 will contain error bits less than a corresponding number and (2) decoding for the data chunk will fail.

The control unit 110 may compare the calculated cumulative failure probability CP to the target decoding failure probability, and determine whether the target decoding failure probability is guaranteed to the memory device 200. When the cumulative failure probability CP corresponding to the maximum number of error bits (e.g., “30”) is equal to or less than the target decoding failure probability, the memory device 200 may be determined to guarantee the target decoding failure probability.

On the other hand, when the cumulative failure probability CP corresponding to the maximum number of error bits (e.g., “30”) is greater than the target decoding failure probability, the memory device 200 may be determined not to guarantee the target decoding failure probability. The control unit 110 may determine the number of error bits as the effective number corresponding to the maximum cumulative failure probabilities CP equal to or less than the target decoding failure probability. The effective number may indicate the maximum number of error bits, which can guarantee the target decoding failure probability as the probability that decoding of the ECC unit 120 for the memory device 200 will fail with the maximum number of error bits. The calculated effective number may be suggested as a development standard for the memory device 200.

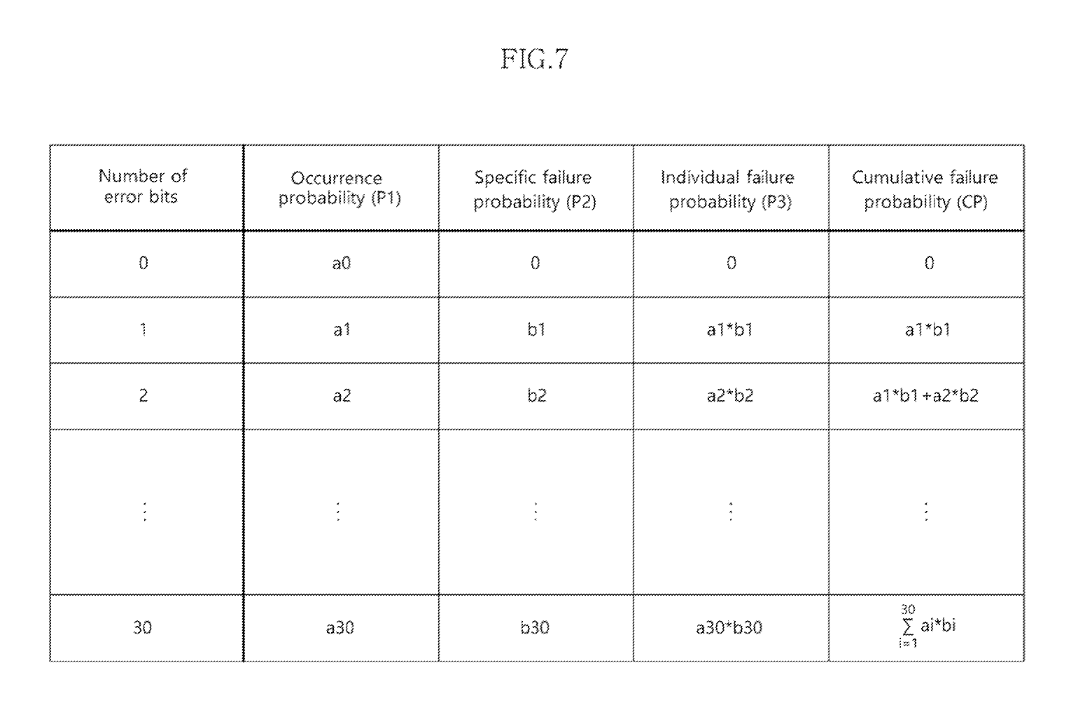

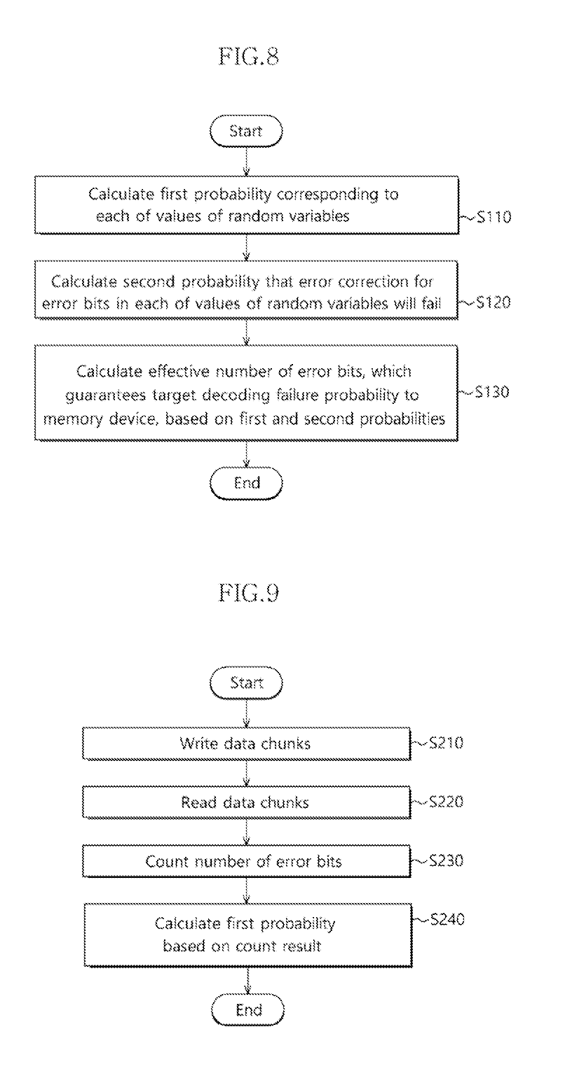

FIG. 8 is a flowchart illustrating a test method according to an embodiment of the present invention. The test method may be performed through the test system 10 of FIG. 1,

Referring to FIG. 8, when random variable is the number of error bits, the test device 100 may calculate the first probability or the occurrence probability P1 corresponding to each of the values of the random variable for a data chunk read from the memory device 200 at step S110.

At step S120, the test device 100 may calculate the second probability or the specific failure probability P2 corresponding to the respective values of the random variable.

At step S130, the test device 100 may determine whether the target decoding failure probability is guaranteed to the memory device 200, based on the first probability and the second probability, and calculate the effective number corresponding to the number of error bits, which guarantees the target decoding failure probability.

FIG. 9 is a flowchart illustrating the test method according to the embodiment of the present invention. The procedure illustrated in FIG. 9 may correspond to an embodiment of step S110 of FIG. 8.

Referring to FIG. 9, the test device 100 may write a plurality of data chunks to the memory device 200 at step S210.

At step S220, the test device 100 may read the plurality of data chunks from the memory device 200.

At step S230, the test device 100 may count the number of error bits contained in each of the data chunks,

At step S240, the test device 100 may calculate the first probability or the occurrence probability P1 based on the count result. The first probability or the occurrence probability P1 may be calculated based on the ratio of the number of times that a predetermined number of error bits occurred to the number of times that the plurality of data chunks were read.

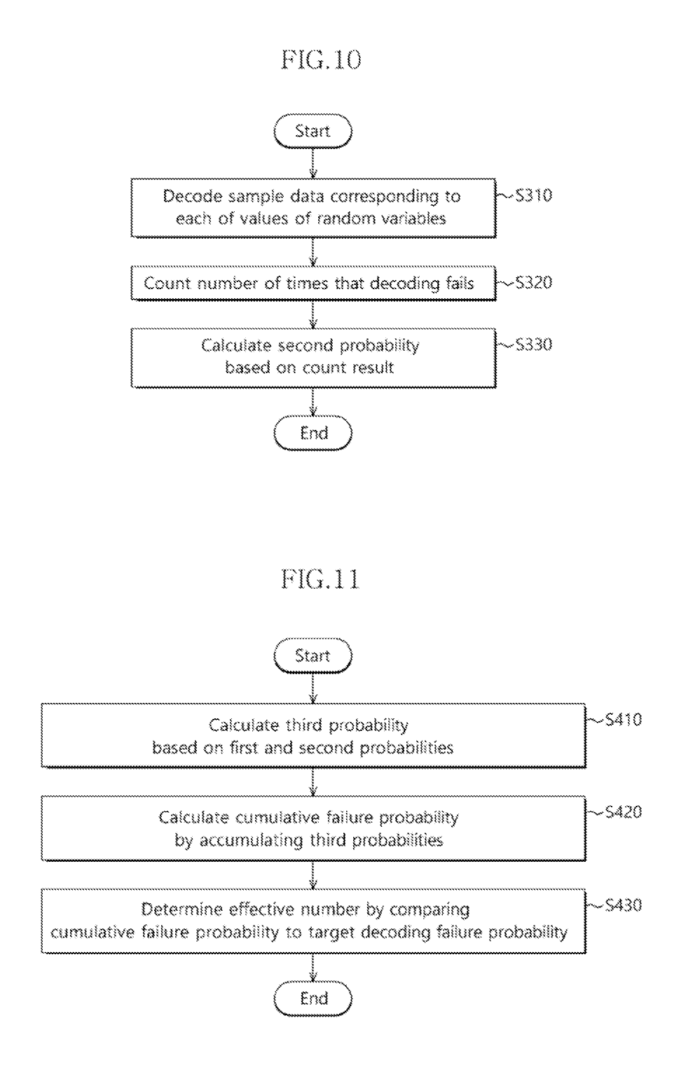

FIG. 10 is a flowchart illustrating the test method according to the embodiment of the present invention. The procedure illustrated in FIG. 10 may correspond to an embodiment of step S120 of FIG. 8.

Referring to FIG. 10, the test device 100 may decode a plurality of sample data corresponding to each of the values of the random variable at step S310. Each of the sample data may have a different data pattern, and contain a predetermined number of error bits of different locations.

At step S320, the test device 100 may count the number of times that decoding failed for the plurality of sample data.

At step S330, the test device 100 may calculate the second probability or the specific failure probability P2 based on the count result. The second probability P2 or the specific failure probability P2 may be calculated on the basis of the ratio of the number of times that decoding failed for the predetermined number of error bits to the number of times that the plurality of sample data were decoded.

FIG. 11 is a flowchart illustrating the test method according to the embodiment of the present invention. The procedure illustrated in FIG. 11 may correspond to an embodiment of step S130 of FIG. 8.

Referring to FIG. 11, the test device 100 may calculate the third probability or the individual failure probability P3 for each of the values of the random variable based on the first probability P1 and the second probability P2 at step S410. The third probability P3 may indicate the probability that a data chunk will contain a corresponding number of error bits and decoding for the corresponding data chunk will fail.

At step S420, the test device 100 may calculate the, cumulative failure probability CP by accumulating the third probabilities P3 for the respective values of the random variable.

At step S430, the test device 100 may determine whether the target decoding failure probability is guaranteed to the memory device 200 by comparing the cumulative failure probability to the target decoding failure probability, and determine the effective number. When the cumulative failure probability is equal to or less than the target decoding failure probability, the test device 100 may s determine that the target decoding failure probability is guaranteed to the memory device 200. The test device 100 may determine the maximum value, which satisfies that the cumulative failure probability is equal to or less than the target decoding failure probability, as the effective number of the memory device 200 among the values of the random variable.

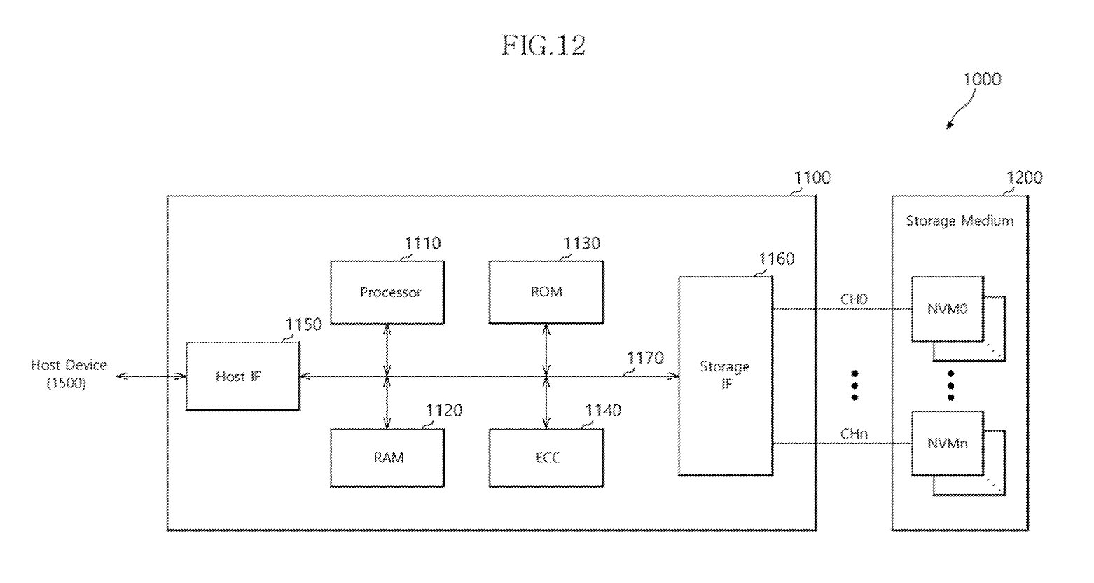

FIG. 12 is a block diagram illustrating a data storage device 1000 according to an embodiment of the present invention.

The data storage device 1000 may be configured by a Personal Computer Memory Card International Association (PCMCIA) card, a compact flash (CF) card, a smart media card, a memory stick, a multimedia card (MMC), an embedded MMC (eMMC), a reduced-size multimedia card (RS-MMC) and a micro-size version of MMC (MMC-micro), a secure digital (SD) card, a mini secure digital (mini-SD) and a micro secure digital (micro-SD), a universal flash storage (UFS), and/or a solid state drive (SSD).

The data storage device 1000 ray include a controller 1100 and a storage medium 1200.

The controller 1100 may control data exchange between a host device 1500 and the storage medium 1200. The controller 1100 may include a processor 1110, a RAM 1120, a ROM 1130, an ECC unit 1140, a host interface 1150, and a storage interface 1160.

The processor 1110 may control overall operations of the controller 1100. The processor 1110 may store data in the storage medium 1200 according to a request of the host device 1500, and read the stored data from the storage medium 1200. The processor 1110 may control an internal operation of the data storage device 1000, such as a merge operation or wear leveling operation, in order to efficiently manage the storage medium 1200.

The RAM 1120 may store a program and program data which are used by the processor 1110. The RAM 1120 may temporarily store data transmitted from the host interface 1150, before the data are transmitted to the storage medium 1200. Furthermore, the RAM 1120 may temporarily store data transmitted from the storage medium 1200, before the data are transmitted to the host device 1500.

The ROM 1130 may store a program code read by the processor 1110. The program code may include commands which are processed by the processor 1110 to control internal units of the controller 1100.

The ECC unit 1140 may encode data to be stored in the storage medium 1200, and decode data read from the storage medium 1200. The ECC unit 1140 may detect and correct an error which occurred in data, according to an ECC algorithm. The ECC unit 1140 may be configured and operated in substantially the same manner as the ECC unit 120 of the test system 10 illustrated in FIG. 1. That is, the ECC unit 1140 may verify the target decoding failure probability for each of nonvolatile memory devices NVM0 to NVMn through the test system 10.

The host interface 1150 may exchange requests and data with the host device 1500.

The storage interface 1160 may transmit control signals and data to the storage medium 1200. The storage interface 1160 may receive data from the storage medium 1200. The storage interface 1160 may be coupled to the storage medium 1200 through a plurality of channels CH0 to CHn.

The storage medium 1200 may include a plurality of nonvolatile memory devices NVM0 to NVMn. Each of the nonvolatile, memory devices NVM0 to NVMn may perform a write operation and a read operation according to control of the controller 1100. Each of the nonvolatile memory devices NVM0 to NVMn may be configured and operated in substantially the same manner as the memory device 200 illustrated in FIG. 1.

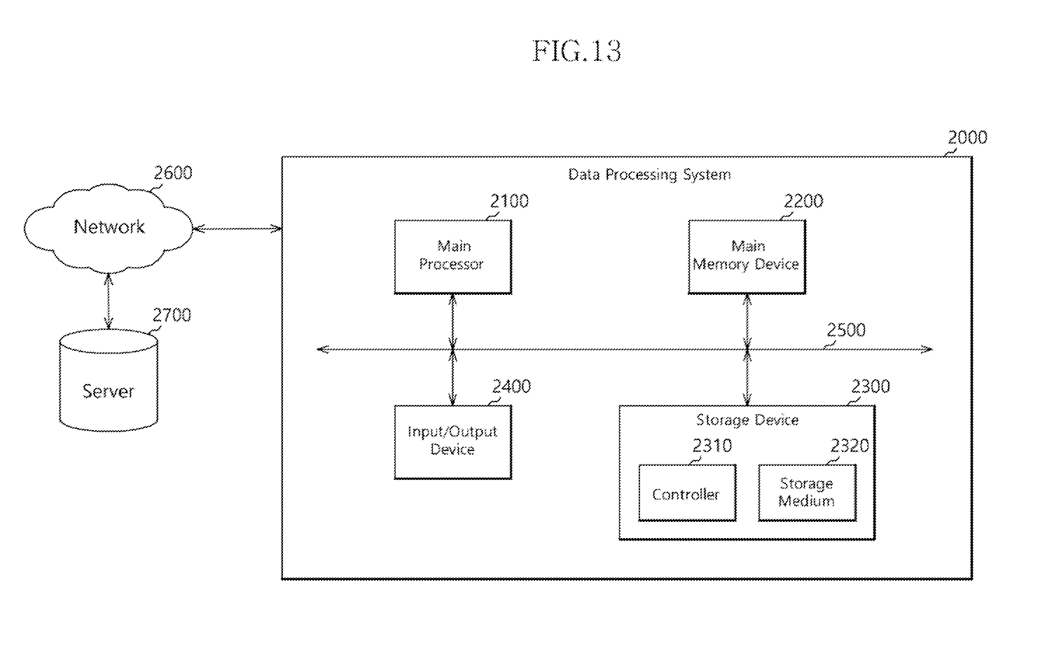

FIG. 13 is a block diagram illustrating a data processing system 2000 to which the data storage device according to the embodiment of the present invention is applied.

The data processing system 2000 may include a computer, a laptop computer, a net-book computer, a smart phone, a digital TV, a digital camera, a navigation system and the like. The data processing system 2000 may include a main processor 2100, a main memory device 2200, a storage device 2300, and an input/output device 2400. The internal units of the data processing system 2000 may exchange data and control signals through a system bus 2500.

The main processor 2100 may control overall operations of the data processing system 2000. The main processor 2100 may include a central processing unit (CPU) such as a microprocessor. The main processor 2100 may execute software for an operating system, an application, or a device driver, on the main memory device 2200.

The main memory device 2200 may store a program and program data which are used by the main processor 2100. The main memory device 2200 may temporarily store data to be transmitted to the storage device 2300 and the input/output device 2400.

The storage device 2300 may include a memory controller 2310 and a storage medium 2320. The storage device 2300 may be configured and operated in substantially the same manner as the data storage device of FIG. 12.

The input/output device 2400 may include a keyboard, a scanner, a touch screen, and a mouse which can exchange information with a user. For example, the input/output device 2400 may receive a command for controlling the data processing system 2000 from a user or provide a processing result to the user.

In another embodiment, the data processing system 2000 may communicate with one or more servers 2700 through a network 2600 such as LAN (Local Area Network), WAN (Wide Area Network), or a wireless network. The data processing system 2000 may include a network interface (not illustrated) for connecting to the network 2600.

While certain embodiments have been described above, it will be understood to those skilled in the art that the embodiments s described are by way of example only. Accordingly, the test system and method described herein should not be limited based on the described embodiments. Rather, the test system and method described herein should only be limited in light of the claims that follow when taken in conjunction with the above description and accompanying drawings.

What is claimed is:

1. A test system comprising:
a memory device suitable for reading a stored data chunk; and
a test device suitable for calculating a cumulative failure probability that the data chunk will contain a predetermined number of error bits or less and decoding for the data chunk will fail.

2. The test system according to claim 1,
wherein the test device calculates an individual failure probability that the data chunk will contain error bits of respective values of the predetermined number and decoding for the data chunk containing error bits of the respective values of the predetermined number will fail, and
wherein the test device calculates the cumulative failure probability by accumulating individual failure probabilities for the respective values of the predetermined number.

3. The test system according to claim 2, wherein the test device calculates the individual failure probability based on an occurrence probability that the data chunk will contain the predetermined number of error bits.

4. The test system according to claim 3, wherein the test device writes a plurality of data chunks to the memory device, reads the plurality of data chunks from the memory device, counts a number of error bits contained in each of the data chunks, and calculates the occurrence probability based on a count result

5. The test system according to claim 2, wherein the test device calculates the individual failure probability based on a specific failure probability that decoding for sample data containing the predetermined number of error bits will fail.

6. The test system according to claim 5, wherein the test device decodes a plurality of sample data containing the predetermined number of error bits, counts a number of times that decoding fails for the plurality of sample data, and calculates the specific failure probability based on a count result.

7. The test system according to claim 1, wherein the test device evaluates performance of the memory device by comparing the cumulative failure probability to a target decoding failure probability.

8. A test system comprising:
a memory device; and
a test device suitable for, calculating a first probability corresponding to each of values of a random variable, which is a number of error bits, for a data chunk read from the memory device, calculating a second probability that error correction for error bits in each of the values of the random variable will fail, and calculating an effective number corresponding to a number of error bits which guarantees a target decoding failure probability to the memory device based on the first probability and the second probability.

9. The test system according to claim 8, wherein the test device writes a plurality of data chunks to the memory device, reads the plurality of data chunks from the memory device, counts a number of error bits contained in each of the data chunks, and calculates the first probability based on a count result.

10. The test system according to claim 8, wherein the test device decodes a plurality of sample data corresponding to each of the values of the random variable, counts a number of times that decoding fails for the plurality of sample data, and calculates the second probability based on a count result.

11. The test system according to claim 8, wherein the test device calculates a third probability for respective values of the random variable that the data chunk will contain error bits of the respective values of the random variable and decoding for the data chunk will fail based on the first probability and the second probability, calculates a cumulative failure probability by accumulating third probabilities for the respective values of the random variable, and determines the effective number by comparing the cumulative failure probability to the target decoding failure probability.

12. The test system according to claim 1, wherein the effective number is the maximum value among values of the random variable which satisfy that the cumulative failure probability is equal to or less than the target decoding failure probability.

13. A test method comprising:
calculating a first probability corresponding to each of values of the random variable, which is a number of error bits, for a data chunk read from a memory device;
calculating a second probability that error correction for error bits in each of the values of the random variable will fail; and
calculating an effective number corresponding to a number of error bits which guarantees a target decoding failure probability to the memory device based on the first probability and the second probability.

14. The test method according to claim 13, wherein the calculating of the first probability comprises:
writing a plurality of data chunks to the memory device;
reading the plurality of data chunks from the memory device;
counting a number of error bits contained in each of the data chunks; and
calculating the first probability based on a count result.

15. The test method according to claim 13, wherein the calculating of the second probability comprises:
decoding a plurality of sample data corresponding to each of the values of the random variable;
counting a number of times that decoding fails for the plurality of sample data; and
calculating the second probability based on a count result.

16. The test method according to claim 13, wherein the calculating of the effective number comprises:
calculating a third probability for respective values of the random variable that the data chunk will contain error bits of the respective values of the random variable and decoding for the data chunk will fail based on the first probability and the second probability;
calculating a cumulative failure probability by accumulating third probabilities for the respective values of the random variable; and
determining the effective number by comparing the cumulative failure probability and the target decoding failure probability.

17. The test method according to claim 16, wherein the effective number is the maximum value among values of the random variable which satisfy that the cumulative failure probability is equal to or less than the target decoding failure probability.
